(19) United States
(12) Patent Application Publication
(10) Pub. No.: US 2025/0175140 A1
(43) Pub. Date: May 29, 2025

(54) STRUCTURE OF ACOUSTIC WAVE FILTER

(71) Applicant: SHANGHAI XIN OU INTEGRATED TECHNOLOGY CO., LTD., Shanghai (CN)

(72) Inventor: Pengcheng Zheng, Shanghai (CN)

(21) Appl. No.: 18/841,392

(22) PCT Filed: May 17, 2023
(86) PCT No.: PCT/CN2023/094798

§ 371 Date: Aug. 26, 2024

(30) Foreign Application Priority Data
Jun. 21, 2022 (CN) 202210732486.2

(51) Int. Cl. H03H 9/02; H03H 9/25; H03H 9/64

(52) U.S. Cl. CPC H03H 9/02732; H03H 9/02818; H03H 9/64; H03H 9/25

(57) ABSTRACT

A structure of an acoustic wave filter includes: parallel resonators and series resonators, where the parallel resonators and the series resonators are cascaded; each of the parallel resonators includes a first supporting substrate, a first piezoelectric thin film, and a first electrode array; the first piezoelectric thin film is disposed on the first supporting substrate, and the first electrode array is disposed on the first piezoelectric thin film; the first electrode array includes a first interdigital electrode array and a first reflection grating array; and a quantity of pairs of first reflection gratings of at least one of the parallel resonators is less than or equal to a first preset threshold, and the first preset threshold is less than 5. The present disclosure can effectively suppress a fluctuation in a passband while ensuring high performance of the filter.

### TECHNICAL FIELD

The present disclosure relates to the technical field of preparation of heterogeneous integrated devices, and in particular, to a structure of an acoustic wave filter.

### BACKGROUND

With advantages of miniaturization, a low cost, and high performance, an acoustic wave filter becomes the only choice for a radio frequency (RF) filter of a mobile terminal. A surface acoustic wave (SAW) filter is an important branch technology of the acoustic wave filter. However, a traditional SAW filter based on a piezoelectric material has a low operating frequency and a high insertion loss. An existing high-performance SAW filter based on a structure sequentially including an electrode, a piezoelectric thin film, and a supporting layer has a spurious wave on a right side of an anti-resonant point, resulting in a strong fluctuation in a passband of the filter. In an existing scheme, the spurious wave is suppressed by increasing a thickness of the piezoelectric thin film to at least 10 μm. But this scheme sacrifices overall performance of the SAW filter, such as a frequency, an insertion loss, and a bandwidth.

### SUMMARY

In order to solve problems of a low operating frequency and a high insertion loss of existing SAW filters, an embodiment of the present disclosure provides a structure of an acoustic wave filter, including:

parallel resonators and series resonators, where the parallel resonators and the series resonators are cascaded;

each of the parallel resonators includes a first supporting substrate, a first piezoelectric thin film, and a first electrode array, where the first piezoelectric thin film is disposed on the first supporting substrate, and the first electrode array is disposed on the first piezoelectric thin film;

the first electrode array includes a first interdigital electrode array and a first reflection grating array; and

a quantity of pairs of first reflection gratings of at least one of the parallel resonators is less than or equal to a first preset threshold, and the first preset threshold is less than 5.

Further, each of the series resonators includes a second supporting substrate, a second piezoelectric thin film, and a second electrode array;

the second piezoelectric thin film is disposed on the second supporting substrate, and the second electrode array is disposed on second piezoelectric thin film;

the second electrode array includes a second interdigital electrode and a second reflection grating array; and

a quantity of pairs of second reflection gratings of at least one of the series resonators is greater than a second preset threshold, and the second preset threshold is greater than the first preset threshold.

Further, a ratio of a thickness of the piezoelectric thin film to a spacing between centers of first interdigital electrodes in the first interdigital electrode array may be less than a third preset threshold.

Further, for the at least one of the parallel resonators, the first reflection grating array may include a first reflection grating sub-array and a second reflection grating sub-array;

the first reflection grating sub-array is disposed on one end portion of the first interdigital electrode array;

the second reflection grating sub-array is disposed on the other end portion of the first interdigital electrode array;

a quantity of pairs of first reflection grating sub-arrays is less than or equal to the first preset threshold; and

a quantity of pairs of second reflection grating sub-arrays is less than or equal to the first preset threshold.

Further, for the at least one of the parallel resonators, the first reflection grating array may include a first reflection grating sub-array and a second reflection grating sub-array;

the first reflection grating sub-array is disposed on one end portion of the first interdigital electrode array;

the second reflection grating sub-array is disposed on the other end portion of the first interdigital electrode array;

a quantity of pairs of first reflection grating sub-arrays is less than or equal to the first preset threshold; and

a quantity of pairs of second reflection grating sub-arrays is greater than the first preset threshold.

Further, for the at least one of the parallel resonators, the first reflection grating array may include a first reflection grating sub-array;

the first reflection grating sub-array is disposed on an end portion of the first interdigital electrode array; and

a quantity of pairs of first reflection grating sub-arrays is less than or equal to the first preset threshold.

Further, for the at least one of the parallel resonators, the first reflection grating array may include a first reflection grating sub-array;

the first reflection grating sub-array is disposed on an end portion of the first interdigital electrode array; and

a quantity of pairs of first reflection grating sub-arrays is greater than the first preset threshold.

Further, each of the parallel resonators may further include a dielectric layer;

the dielectric layer is disposed on the supporting substrate;

a ratio of a thickness of the dielectric layer to a spacing between centers of first interdigital electrodes in the first interdigital electrode array is less than a fourth preset threshold, and the fourth preset threshold is less than a third preset threshold.

Further, the supporting substrate may be made of high-resistance silicon, quartz, sapphire, or silicon carbide.

Further, the first reflection grating electrode array may be arranged to form a slant angle with a normal direction of the first electrode array;

the first interdigital electrode array may be arranged to form a slant angle with the normal direction of the first electrode array; and

the slant angle may be set to within a range of [−10°, 10°].

The embodiments of the present disclosure have following beneficial effects:

The embodiments of the present disclosure provide a structure of an acoustic wave filter, including: parallel resonators and series resonators. The parallel resonators and the series resonators are cascaded. Each of the parallel resonators includes a first supporting substrate, a first piezoelectric thin film, and a first electrode array. The first piezoelectric thin film is disposed on the first supporting substrate, and the first electrode array is disposed on the first piezoelectric thin film. The first electrode array includes a first interdigital electrode array and a first reflection grating array. A quantity of pairs of first reflection gratings of at least one of the parallel resonators is less than or equal to a first preset threshold, and the first preset threshold is less than 5. Based on the embodiments of the present disclosure, a spurious wave mode of the parallel resonators can be suppressed by reducing a quantity of reflection gratings of the parallel resonators, thus effectively suppressing a fluctuation in a passband while ensuring high performance of the filter.

### BRIEF DESCRIPTION OF THE DRAWINGS

To describe the technical solutions and advantages of the embodiments of the present disclosure or in the prior art more clearly, the following briefly describes the accompanying drawings required for describing the embodiments or the prior art. Apparently, the accompanying drawings in the following description merely show some embodiments of the present disclosure, and a person of ordinary skill in the art may still derive other accompanying drawings from these accompanying drawings without creative efforts.

FIG. 1 is a first schematic diagram of a structure of an acoustic wave filter according to an embodiment of the present disclosure;

FIG. 2 shows response curves of a traditional acoustic wave resonator and an acoustic wave filter;

FIG. 3 shows a simulated admittance curve of a SAW filter based on a piezoelectric thin film material with a subwavelength thickness, and a vibration mode diagram of a corresponding spurious wave mode according to an embodiment of the present disclosure;

FIG. 4 is a second schematic diagram of a structure of an acoustic wave filter according to an embodiment of the present disclosure;

FIG. 5 shows responses of resonators with a same quantity of pairs of interdigital electrodes and different quantities of pairs of reflection gratings according to an embodiment of the present disclosure;

FIG. 6 is a schematic structural diagram of a resonator according to an embodiment of the present disclosure;

FIG. 7 is a schematic top view of a resonator according to an embodiment of the present disclosure;

FIG. 8 is a third schematic diagram of a structure of an acoustic wave filter according to an embodiment of the present disclosure;

FIG. 9 is a fourth schematic diagram of a structure of an acoustic wave filter according to an embodiment of the present disclosure;

FIG. 10 shows a response of an acoustic wave filter shown in FIG. 9 according to an embodiment of the present disclosure; and

FIG. 11 is a fifth schematic diagram of a structure of an acoustic wave filter according to an embodiment of the present disclosure.

### DETAILED DESCRIPTION

To make the objectives, technical solutions, and advantages of the present disclosure clearer, the embodiments of the present disclosure will be further described in detail with reference to the accompanying drawings. Apparently, the embodiments described are merely some rather than all of the embodiments of the present disclosure. All other embodiments obtained by those of ordinary skill in the art based on the embodiments of the present disclosure without creative efforts should fall within the protection scope of the present disclosure.

As used herein, “an embodiment” refers to a particular feature, structure, or characteristic that may be included in at least one implementation of the present disclosure. In the description of the embodiments of the present disclosure, it should be understood that the terms such as “first”, “second”, “third”, and “fourth” are used merely for a descriptive purpose, and should not be construed as indicating or implying a relative importance, or implicitly indicating a quantity of indicated technical features. Therefore, the features defined by the terms such as “first”, “second”, “third”, and “fourth” may explicitly or implicitly include one or more of the features. Further, the terms such as “first”, “second”, “third”, and “fourth” are intended to distinguish between similar objects, rather than to necessarily describe a specific order or sequence. It should be understood that the data used in such a manner may be exchanged under proper conditions to make it possible for the described embodiments of the present disclosure to be implemented in a sequence except those illustrated or described herein. Moreover, the terms “include”, “have”, “is/are”, and any variations thereof mean to cover non-exclusive inclusion.

The following describes specific embodiments of a structure of an acoustic wave filter in the present disclosure. FIG. 1 is a first schematic diagram of a structure of an acoustic wave filter according to an embodiment of the present disclosure. This specification provides a composition structure as shown in the embodiments or in the accompanying drawings, and more or fewer modules or components may be included based on conventional or non-creative efforts. The composition structure listed in the embodiments is one of numerous composition structures and is not the only one composition structure. In actual execution, the composition structure shown in the embodiments or in the accompanying drawings may be followed.

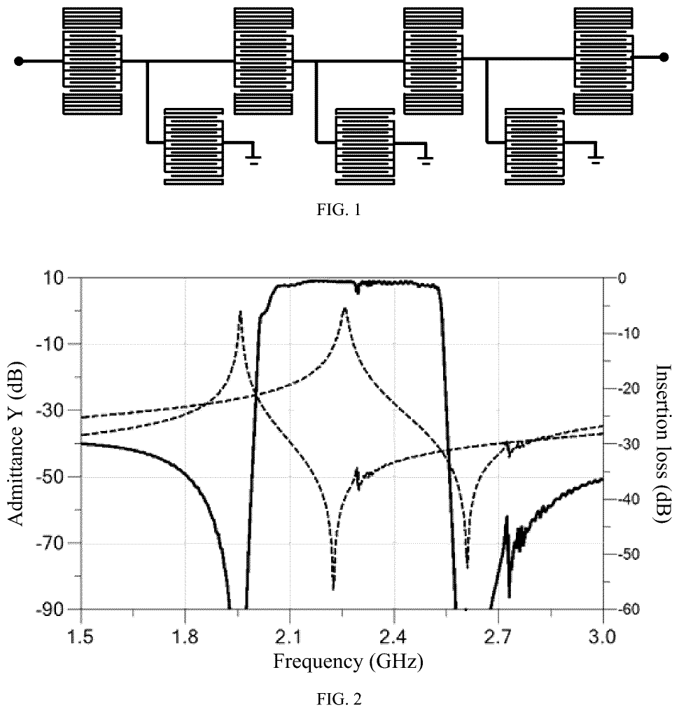

An acoustic wave resonator is a basic unit of the acoustic wave filter, and its performance directly affects performance of the constructed filter. The acoustic wave filter is constituted by cascading several series resonators and parallel resonators. In the acoustic wave filter, a resonant frequency point of the series resonator is basically the same as an anti-resonant frequency point of the parallel resonator. Generally, there are more than five pairs of reflection gratings in a resonator, which means that there are more than ten reflection gratings in the resonator, to prevent an acoustic wave from leaking to left and right sides, thereby ensuring a high Q value (which is 2× times a ratio of stored energy to consumed energy in each cycle of the resonator) of the resonator. FIG. 2 shows response curves of a traditional acoustic wave resonator and a filter based on a piezoelectric thin film with a subwavelength thickness. The dashed lines represent the response curves of the acoustic wave resonator, while the solid lines represent the response curves of the filter. In the acoustic wave filter, an electrode cycle may be 1.85 μm for the series resonator and 2.3 μm for the parallel resonator, a quantity N of pairs of interdigital electrodes (Interdigital transducer, IDT) may be 80 for both of them, and a quantity N_ref of pairs of left and right reflection gratings may be 10 for both of them. The series resonator and the parallel resonator can generate a spurious wave at 2.72 GHz and 2.3 GHZ respectively, and a violent jitter may be caused in a corresponding filter response, making the filter unavailable. A jitter in a passband of the filter is caused by the parallel resonator.

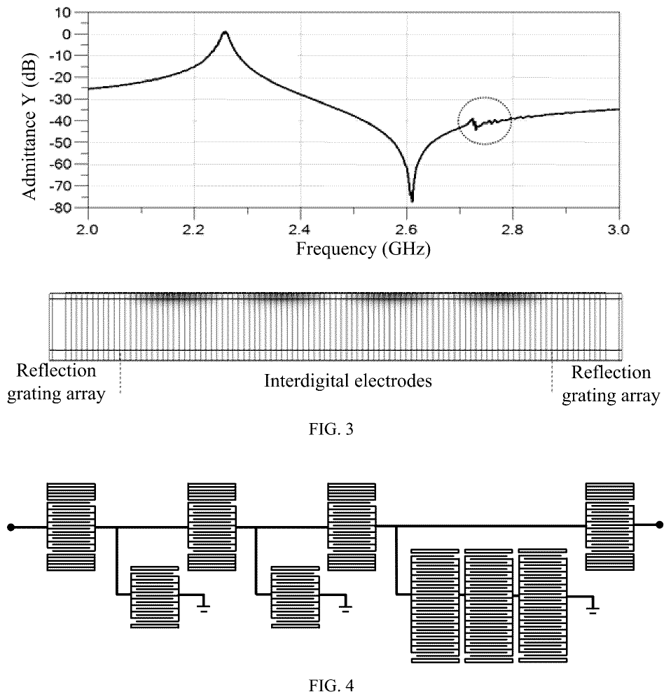

FIG. 3 shows a simulated admittance curve of a SAW filter based on a piezoelectric thin film material with a subwavelength thickness, and a vibration mode diagram of a corresponding spurious wave mode according to an embodiment of the present disclosure. The SAW filter is constituted by a 120 nm aluminum electrode and a 500 nm substrate made of X-cut lithium niobate and 4H SiC. A width of one pair of electrodes, namely, an electrode cycle λ, is equal to 1.85 μm, a quantity N of pairs of interdigital electrodes is 80, and a quantity N-ref of pairs of left and right reflection gratings is 10. The simulated admittance curve shows that the spurious wave mode (the dashed circle) is located not far from a right side of an anti-resonant point. The vibration mode diagram of the spurious wave mode shows that a spurious wave is mainly caused by a high-order standing wave formed between reflection grating arrays by an acoustic wave.

Specifically, as shown in FIG. 1, the acoustic wave filter includes parallel resonators and series resonators, where the parallel resonators and the series resonators are cascaded.

In this embodiment of the present disclosure, each of the series resonators includes a first supporting substrate, a first piezoelectric thin film, and a first electrode array. The first piezoelectric thin film is disposed on the first supporting substrate, and the first electrode array is disposed on the first piezoelectric thin film. The first electrode array includes a first interdigital electrode array and a first reflection grating array. A quantity of pairs of first reflection gratings of at least one of the parallel resonators is less than or equal to a first preset threshold, and the first preset threshold may be less than 5.

In some possible implementations, for the at least one of the parallel resonators, the first reflection grating array may include a first reflection grating sub-array and a second reflection grating sub-array. The first reflection grating sub-array may be disposed on one end portion of the first interdigital electrode array, and the second reflection grating sub-array may be disposed on the other end portion of the first interdigital electrode array. A quantity of pairs of first reflection grating sub-arrays may be less than or equal to the first preset threshold. A quantity of pairs of second reflection grating sub-arrays is less than or equal to the first preset threshold. As shown in FIG. 1, in each of the parallel resonators, the quantity N_ref of pairs of first reflection grating sub-arrays located on the one end portion of the first interdigital electrode array is less than or equal to 3, and the quantity N_ref of pairs of second reflection grating sub-array located on the other end portion of the first interdigital electrode array is less than or equal to 3.

In some possible implementations, for the at least one of the parallel resonators, the first reflection grating array may include a first reflection grating sub-array and a second reflection grating sub-array. The first reflection grating sub-array may be disposed on one end portion of the first interdigital electrode array, and the second reflection grating sub-array may be disposed on the other end portion of the first interdigital electrode array. A quantity of pairs of first reflection grating sub-arrays may be less than or equal to the first preset threshold. A quantity of pairs of second reflection grating sub-arrays is less than or equal to the first preset threshold. A quantity of pairs of first interdigital electrode arrays is equal to or greater than the first preset threshold. FIG. 4 is a second schematic diagram of a structure of an acoustic wave filter according to an embodiment of the present disclosure. Herein, a single resonator can be decomposed into a plurality of series resonators. In the decomposed series resonators, a quantity N_ref of pairs of first reflection grating sub-arrays located on the one end portion of the first interdigital electrode array is less than or equal to 3, and a quantity N_ref of pairs of second reflection grating sub-array located on the other end portion of the first interdigital electrode array is less than or equal to 3. A quantity of pairs of first interdigital electrodes is greater than 100. A quantity of reflection gratings of the parallel resonator is decreased, and a quantity of interdigital electrode arrays of the decomposed series resonator is increased. In this way, a large quantity of reflection gratings of the series resonator can increase a Q value of the resonator, thereby compensating for a Q value loss caused by a small quantity of reflection gratings of the parallel resonator.

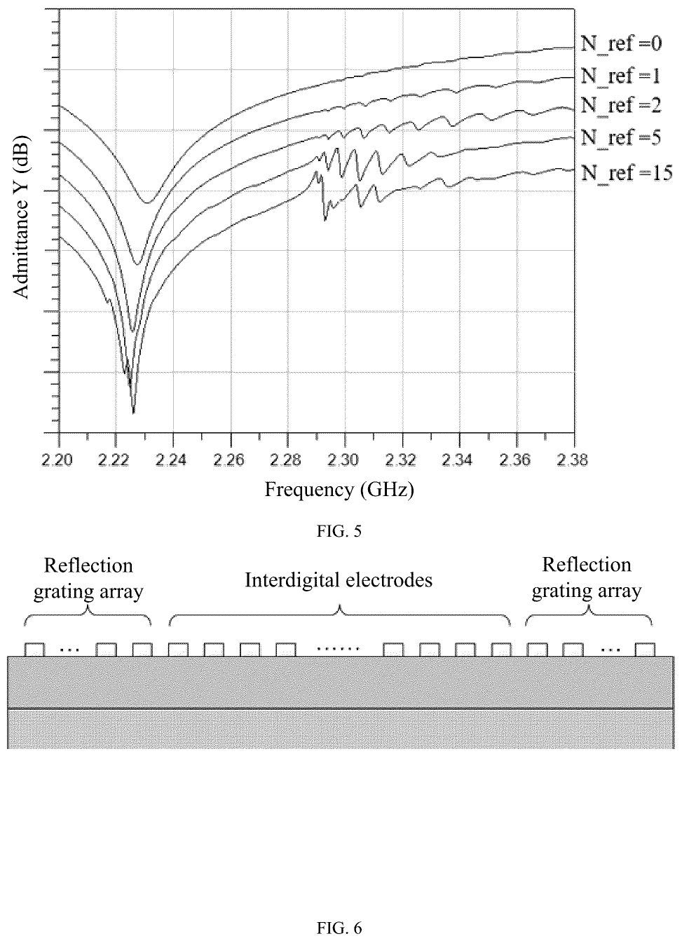

FIG. 5 shows responses of resonators with a same quantity of pairs of interdigital electrodes and different quantities of pairs of reflection gratings according to an embodiment of the present disclosure. As shown in FIG. 5, with an increase in a quantity of pairs of reflection gratings, intensity of a spurious wave continues to increase, and a sharpness degree of anti-resonance of a filter, namely, a Q value, also increases continuously. This indicates that the quantity of pairs of reflection gratings is crucial for a localization effect of a sound field. A spurious wave mode of the parallel resonators can be suppressed by reducing the quantity of reflection gratings of the parallel resonators, thus effectively suppressing a fluctuation in a passband while ensuring high performance of the filter.

In some possible implementations, a ratio of a thickness of the first piezoelectric thin film to a spacing between centers of first interdigital electrodes in the first interdigital electrode array may be less than a third preset threshold. Optionally, the ratio of the thickness h of the first piezoelectric thin film to the spacing p between the centers of the first interdigital electrodes in the first interdigital electrode array may be less than 1.6, in other words, h<0.8λ, where λ can represent a width of one pair of interdigital electrodes, namely, a device cycle.

In some possible implementations, an electrode thickness in the first electrode array may be greater than 60 nm but less than 0.05 p.

In some possible implementations, the first supporting substrate may be made of any one of high-resistance silicon, quartz, sapphire, and SiC.

In some possible implementations, the first piezoelectric thin film may be made of lithium niobate or lithium tantalate. A crystal cut of the first piezoelectric thin film may be a Z-cut, an X-cut, a Y-cut, or an oblique cut from Y15° to Y55°. The thickness of the first piezoelectric thin film may be within a range of [200 nm, 800 nm].

In some possible implementations, an acoustic wave mode of the resonator may be a shear-horizontal surface acoustic wave (SH-SAW).

In some possible implementations, the first reflection grating electrode array may be arranged to form a slant angle with a normal direction of the first electrode array, and the first interdigital electrode array may be arranged to form a slant angle with the normal direction of the first electrode array. The slant angle may be set to within a range of [−10°, 10°]. Optionally, the slant angle may be 10°. The interdigital electrode array and the reflection grating array are disposed on the piezoelectric thin film at the slant angle, which can increase the Q value of the resonator and suppress the spurious wave mode of the parallel resonator.

FIG. 6 is a schematic structural diagram of a resonator according to an embodiment of the present disclosure. FIG. 7 is a schematic top view of a resonator according to an embodiment of the present disclosure. In this embodiment of the present disclosure, each of the parallel resonators may include a first supporting substrate, a dielectric layer, a first piezoelectric thin film, and a first electrode array. The dielectric layer may be disposed on the first supporting substrate, the first piezoelectric thin film may be disposed on the dielectric layer, and the first electrode array may be disposed on the first piezoelectric thin film. The first electrode array may include a first interdigital electrode array and a first reflection grating array. All electrodes in the first interdigital electrode array and the first reflection grating array are uniformly spaced and parallel arranged on the first piezoelectric thin film. A quantity of pairs of first reflection gratings of at least one of the parallel resonators is less than or equal to a first preset threshold, and the first preset threshold may be less than 5. A spurious wave mode of the parallel resonators can be suppressed by reducing a quantity of reflection gratings of the parallel resonators, thus effectively suppressing a fluctuation in a passband while ensuring high performance of the filter. Moreover, the dielectric layer is disposed on the supporting substrate, which can further increase a Q value of the resonator and improve temperature stability of the filter.

In some possible implementations, a ratio of a thickness of the first piezoelectric thin film to a spacing between centers of first interdigital electrodes in the first interdigital electrode array may be less than a third preset threshold. Optionally, the ratio of the thickness h of the first piezoelectric thin film to the spacing p between the centers of the first interdigital electrodes in the first interdigital electrode array may be less than 1.6, in other words, h<0.8λ, where A can represent a width of one pair of interdigital electrodes, namely, a device cycle.

In some possible implementations, the first supporting substrate may be made of any one of high-resistance silicon, quartz, sapphire, and SiC.

In some possible implementations, the first piezoelectric thin film may be made of lithium niobate or lithium tantalate. A crystal cut of the first piezoelectric thin film may be a Z-cut, an X-cut, a Y-cut, or an oblique cut from Y15° to Y55°.

In some possible implementations, the dielectric layer may be made of a non-metallic material such as silicon oxide (SiOₓ), silicon nitride (Si₃N₄), aluminum nitride (AlN), or aluminum oxide (Al₂O₃). Optionally, a ratio of a thickness of the dielectric layer to the spacing between the centers of the first interdigital electrodes in the first interdigital electrode array may be less than a fourth preset threshold, and the fourth preset threshold may be less than the third preset threshold. In an actual application, the ratio of the thickness h′ of the dielectric layer to the spacing p between the centers of the first interdigital electrodes in the first interdigital electrode array may be less than 1.2, in other words, h′<0.8λ, where λ can represent the width of the one pair of interdigital electrodes, namely, the device cycle. The piezoelectric thin film with a subwavelength thickness is used, which can suppress a spurious wave of the parallel resonator to a certain extent while ensuring a low insertion loss of the filter.

In some possible implementations, an acoustic wave mode of the resonator may be shear-horizontal surface acoustic wave (SH-SAW).

In some possible implementations, the first reflection grating electrode array may be arranged to form a slant angle with a normal direction of the first electrode array, and the first interdigital electrode array may be arranged to form a slant angle with the normal direction of the first electrode array. The slant angle may be set to within a range of [−10°, 10°]. Optionally, the slant angle may be 10°. The interdigital electrode array and the reflection grating array are disposed on the piezoelectric thin film at the slant angle, which can increase the Q value of the resonator and suppress the spurious wave mode of the parallel resonator.

In this embodiment of the present disclosure, the series resonator may include a second supporting substrate, a second piezoelectric thin film, and a second electrode array. The second piezoelectric thin film may be disposed on the second supporting substrate, and the second electrode array may be disposed on second piezoelectric thin film. The second electrode array may include a second interdigital electrode array and a second reflection grating array. All electrodes in the second interdigital electrode array and the second reflection grating array are uniformly spaced and parallel arranged on the second piezoelectric thin film. A quantity of pairs of second reflection gratings of at least one of the series resonators is greater than a second preset threshold, and the second preset threshold may be greater than the first preset threshold.

In some possible implementations, the second preset threshold may be equal to or greater than 5. The quantity of reflection gratings of the parallel resonator is decreased, and a quantity of reflection gratings of the series resonator is increased. In this way, the large quantity of reflection gratings of the series resonator can increase the Q value of the resonator, thereby compensating for the Q value loss caused by the small quantity of reflection gratings of the parallel resonator.

In some possible implementations, a ratio of a thickness of the second piezoelectric thin film to a spacing between centers of second interdigital electrodes in the second interdigital electrode array may be less than the third preset threshold. Optionally, the ratio of the thickness h of the second piezoelectric thin film to the spacing p between the centers of the second interdigital electrodes in the second interdigital electrode array may be less than 1.6, in other words, h<0.8λ, where λ can represent the width of the one pair of interdigital electrodes, namely, the device cycle.

In some possible implementations, the second supporting substrate may be made of any one of the high-resistance silicon, the quartz, the sapphire, and the SiC.

In some possible implementations, the second piezoelectric thin film may be made of the lithium niobate or the lithium tantalate. A crystal cut of the second piezoelectric thin film may be the Z-cut, the X-cut, the Y-cut, or the oblique cut from Y15° to Y55°.

In some possible implementations, an acoustic wave mode of the resonator may be the shear-horizontal surface acoustic wave (SH-SAW).

In some possible implementations, the second reflection grating electrode array may be arranged to form a slant angle with a normal direction of the second electrode array, and the second interdigital electrode array may be arranged to form a slant angle with the normal direction of the second electrode array. The slant angle may be set to within a range of [−10°, 10°]. Optionally, the slant angle may be 10°. The interdigital electrode array and the reflection grating array are disposed on the piezoelectric thin film at the slant angle, which can increase the Q value of the resonator and suppress the spurious wave mode of the parallel resonator.

In this embodiment of the present disclosure, the series resonator may include a second supporting substrate medium layer, a dielectric layer, a second piezoelectric thin film, and a second electrode array. The dielectric layer may be disposed on the second supporting substrate, the second piezoelectric thin film may be disposed on the dielectric layer, and the second electrode array may be disposed on the second piezoelectric thin film. The second electrode array may include a second interdigital electrode array and a second reflection grating array. All electrodes in the second interdigital electrode array and the second reflection grating array are uniformly spaced and parallel arranged on the second piezoelectric thin film. A quantity of pairs of second reflection gratings of at least one of the series resonators is greater than a second preset threshold, and the second preset threshold may be greater than the first preset threshold.

In some possible implementations, the second preset threshold may be equal to or greater than 5. The quantity of reflection gratings of the parallel resonator is decreased, and a quantity of reflection gratings of the series resonator is increased. In this way, the large quantity of reflection gratings of the series resonator can increase the Q value of the resonator, thereby compensating for the Q value loss caused by the small quantity of reflection gratings of the parallel resonator.

In some possible implementations, a ratio of a thickness of the second piezoelectric thin film to a spacing between centers of second interdigital electrodes in the second interdigital electrode array may be less than the third preset threshold. Optionally, the ratio of the thickness h of the second piezoelectric thin film to the spacing p between the centers of the second interdigital electrodes in the second interdigital electrode array may be less than 1.6, in other words, h<0.8λ, where A can represent the width of the one pair of interdigital electrodes, namely, the device cycle.

In some possible implementations, the second supporting substrate may be made of any one of the high-resistance silicon, the quartz, the sapphire, and the SiC.

In some possible implementations, the second piezoelectric thin film may be made of the lithium niobate or the lithium tantalate. A crystal cut of the second piezoelectric thin film may be the Z-cut, the X-cut, the Y-cut, or the oblique cut from Y15° to Y55°.

In some possible implementations, an acoustic wave mode of the resonator may be the shear-horizontal surface acoustic wave (SH-SAW).

In some possible implementations, the second reflection grating electrode array may be arranged to form a slant angle with a normal direction of the second electrode array, and the second interdigital electrode array may be arranged to form a slant angle with the normal direction of the second electrode array. The slant angle may be set to within a range of [−10°, 10°]. Optionally, the slant angle may be 10°. The interdigital electrode array and the reflection grating array are disposed on the piezoelectric thin film at the slant angle, which can increase the Q value of the resonator and suppress the spurious wave mode of the parallel resonator.

In this embodiment of the present disclosure, the series resonator may include a second supporting substrate, a second piezoelectric thin film, and a second electrode array. The second piezoelectric thin film may be disposed on the second supporting substrate, and the second electrode array may be disposed on second piezoelectric thin film. The second electrode array may include a second interdigital electrode array and a second reflection grating array. All electrodes in the second interdigital electrode array and the second reflection grating array are uniformly spaced and parallel arranged on the second piezoelectric thin film. A quantity of pairs of second reflection gratings of at least one of the series resonators is greater than a second preset threshold, and the second preset threshold may be greater than the first preset threshold.

In some possible implementations, the second preset threshold may be equal to or greater than 5. The quantity of reflection gratings of the parallel resonator is decreased, and a quantity of reflection gratings of the series resonator is increased. In this way, the large quantity of reflection gratings of the series resonator can increase the Q value of the resonator, thereby compensating for the Q value loss caused by the small quantity of reflection gratings of the parallel resonator. The spurious wave mode of the parallel resonator can be further suppressed, thus effectively suppressing the fluctuation in the passband while ensuring the high performance of the filter.

In some possible implementations, a ratio of a thickness of the second piezoelectric thin film to a spacing between centers of second interdigital electrodes in the second interdigital electrode array may be less than the third preset threshold. Optionally, the ratio of the thickness h of the second piezoelectric thin film to the spacing p between the centers of the second interdigital electrodes in the second interdigital electrode array may be less than 1.6, in other words, h<0.8λ, where λ can represent the width of the one pair of interdigital electrodes, namely, the device cycle.

In some possible implementations, an electrode thickness in the second electrode array may be greater than 60 nm but less than 0.05 p.

In some possible implementations, the second supporting substrate may be made of any one of the high-resistance silicon, the quartz, the sapphire, and the SiC.

In some possible implementations, the second piezoelectric thin film may be made of the lithium niobate or the lithium tantalate. A crystal cut of the second piezoelectric thin film may be the Z-cut, the X-cut, the Y-cut, or the oblique cut from Y15° to Y55°. A thickness of the second piezoelectric thin film may be within a range of [200 nm, 800 nm].

In some possible implementations, the dielectric layer may be made of the non-metallic material such as the SiOₓ, the Si₃N₄, the AlN, or the Al₂O₃. Optionally, a ratio of a thickness of the dielectric layer to a spacing between centers of second interdigital electrodes in the second interdigital electrode array may be less than the fourth preset threshold, and the fourth preset threshold may be less than the third preset threshold. In an actual application, the ratio of the thickness h′ of the dielectric layer to the spacing p between the centers of the second interdigital electrodes in the second interdigital electrode array may be less than 1.2, in other words, h′<0.8λ, where λ can be represented as the width of the one pair of interdigital electrodes, namely, the device cycle. The piezoelectric thin film with the subwavelength thickness is used, which can suppress the spurious wave of the parallel resonator to a certain extent while ensuring the low insertion loss of the filter.

In some possible implementations, an acoustic wave mode of the resonator may be the shear-horizontal surface acoustic wave (SH-SAW).

In some possible implementations, the second reflection grating electrode array may be arranged to form a slant angle with a normal direction of the second electrode array, and the second interdigital electrode array may be arranged to form a slant angle with the normal direction of the second electrode array. The slant angle may be set to within a range of [−10°, 10°]. Optionally, the slant angle may be 10°. The interdigital electrode array and the reflection grating array are disposed on the piezoelectric thin film at the slant angle, which can increase the Q value of the resonator and suppress the spurious wave mode of the parallel resonator.

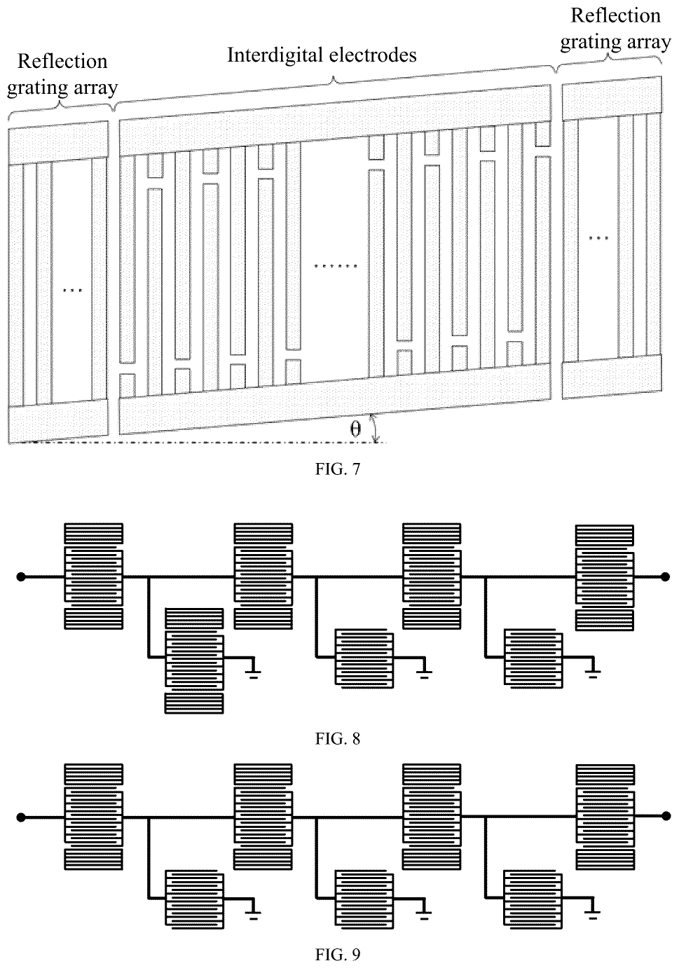

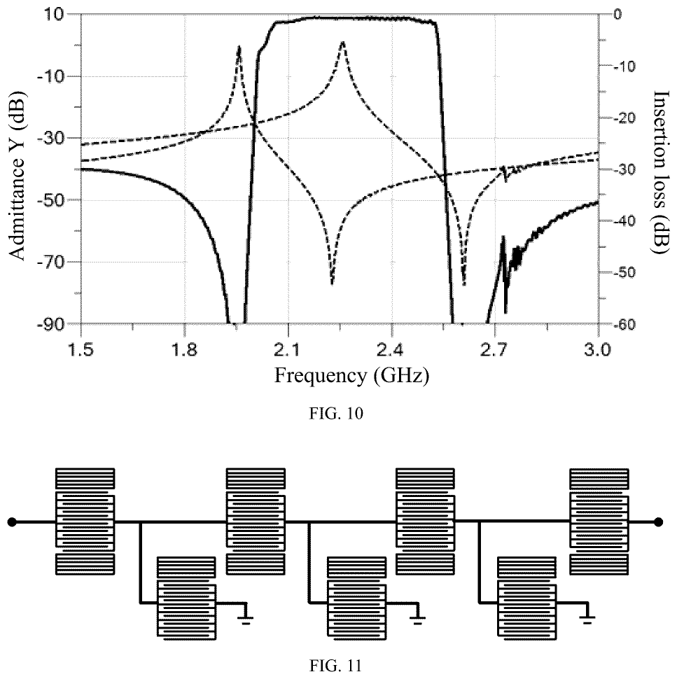

In some possible implementations, for the at least one of the parallel resonators, the first reflection grating array is removed. FIG. 8 is a third schematic diagram of a structure of an acoustic wave filter according to an embodiment of the present disclosure. First reflection grating arrays in two resonators of the parallel resonators are removed. A quantity N_ref of pairs of first reflection grating sub-arrays located on one end portion of a first interdigital electrode array in one resonator is greater than 5, and a quantity N_ref of pairs of second reflection grating sub-arrays located on the other end portion of the first interdigital electrode array in the one resonator is greater than 5. FIG. 9 is a fourth schematic diagram of a structure of an acoustic wave filter according to an embodiment of the present disclosure. First reflection grating arrays in all the parallel resonators are removed. FIG. 10 shows a response of the acoustic wave filter shown in FIG. 9 according to an embodiment of the present disclosure. As shown in FIG. 10, as the spurious wave mode of the parallel resonator is suppressed, the passband of the filter becomes flat. Although the Q value of the parallel resonator is significantly reduced, the insertion loss does not significantly increase compared with that in FIG. 2. This can verify effectiveness and superiority of reducing the quantity of reflection gratings of the parallel resonator, and can effectively suppress the fluctuation in the passband while ensuring the high performance of the filter.

In this embodiment of the present disclosure, for the at least one of the series resonators, the first reflection grating array may include a first reflection grating sub-array. The first reflection grating sub-array may be disposed on one end portion of the first interdigital electrode array, and a quantity of pairs of first reflection sub-arrays may be greater than the first preset threshold. FIG. 11 is a fifth schematic diagram of a structure of an acoustic wave filter according to an embodiment of the present disclosure. In each of the parallel resonators, a quantity N_ref of pairs of first reflection gratings located on the one end portion of the first interdigital electrode array is equal to or greater than 5, and a second reflection grating sub-array located on the other end portion of the first interdigital electrode array is removed.

In this embodiment of the present disclosure, for the at least one of the series resonators, the first reflection grating array may include a first reflection grating sub-array. The first reflection grating sub-array may be disposed on an end portion of the first interdigital electrode array, and a quantity of pairs of first reflection sub-arrays may be less than or equal to the first preset threshold.

According to the structure of an acoustic wave filter provided in the embodiments of the present disclosure, a quantity of reflection gratings of a parallel resonator is decreased, and a quantity of reflection gratings of a series resonator is increased. In this way, a large quantity of reflection gratings of the series resonator can increase a Q value of the resonator, thereby compensating for a Q value loss caused by a small quantity of reflection gratings of the parallel resonator. This can suppress a spurious wave mode of the parallel resonator, and effectively suppress a fluctuation in a passband while ensuring high performance of the filter. A piezoelectric thin film with a subwavelength thickness is used, which can suppress a spurious wave of the parallel resonator to a certain extent while ensuring a low insertion loss of the filter. Moreover, a dielectric layer is disposed on a supporting substrate, which can further increase the Q value of the resonator and improve temperature stability of the filter.

It should be noted that an order of the embodiments of the present disclosure is only for description and does not represent superiority or inferiority of the embodiments. Moreover, although the specific embodiments are described in this specification, there are other embodiments falling in the scope of the attached claims. In some cases, the actions or steps described in the claims may be performed in sequences different from those in the embodiments, and expected results can still be achieved. In addition, the processes depicted in the accompanying drawings do not necessarily require the specific orders or sequential orders shown for achieving the expected results. In some implementations, multitasking and parallel processing are also possible or may be advantageous.

The embodiments in this specification are described in a progressive manner. For same or similar parts between the embodiments, reference may be made to each other. Each embodiment focuses on a difference from other embodiments. For embodiments of an apparatus and an electronic device, since they are basically similar to the method embodiment, the description is relatively simple, and reference can be made to the description of the method embodiment.

The descriptions above are preferred implementations of the present disclosure. It should be noted that for a person of ordinary skill in the art, various improvements and modifications can be made without departing from the principles of the present disclosure. These improvements and modifications should also be regarded as falling into the protection scope of the present disclosure.

1. A structure of an acoustic wave filter, comprising:
parallel resonators and series resonators, wherein the parallel resonators and the series resonators are cascaded;
each of the parallel resonators comprises a first supporting substrate, a first piezoelectric thin film, and a first electrode array, wherein the first piezoelectric thin film is disposed on the first supporting substrate, and the first electrode array is disposed on the first piezoelectric thin film;
the first electrode array comprises a first interdigital electrode array and a first reflection grating array; and
a quantity of pairs of first reflection gratings of at least one of the parallel resonators is less than or equal to a first preset threshold, and the first preset threshold is less than 5.

2. The structure according to claim 1, wherein each of the series resonators comprises a second supporting substrate, a second piezoelectric thin film, and a second electrode array;
the second piezoelectric thin film is disposed on the second supporting substrate, and the second electrode array is disposed on the second piezoelectric thin film;
the second electrode array comprises a second interdigital electrode array and a second reflection grating array; and
a quantity of pairs of second reflection gratings of at least one of the series resonators is greater than a second first preset threshold, and the second preset threshold is greater than the first preset threshold.

3. The structure according to claim 1, wherein a ratio of a thickness of the first piezoelectric thin film to a spacing between centers of adjacent first interdigital electrodes in the first interdigital electrode array is less than a third preset threshold.

4. The structure according to claim 1, wherein for the at least one of the parallel resonators, the first reflection grating array comprises a first reflection grating sub-array and a second reflection grating sub-array;
the first reflection grating sub-array is disposed on one end portion of the first interdigital electrode array;
the second reflection grating sub-array is disposed on the other end portion of the first interdigital electrode array;
a quantity of pairs of first reflection grating sub-arrays is less than or equal to the first preset threshold; and
a quantity of pairs of second reflection grating sub-arrays is less than or equal to the first preset threshold.

5. The structure according to claim 1, wherein for the at least one of the parallel resonators, the first reflection grating array comprises a first reflection grating sub-array and a second reflection grating sub-array;
the first reflection grating sub-array is disposed on one end portion of the first interdigital electrode array;
the second reflection grating sub-array is disposed on the other end portion of the first interdigital electrode array;
a quantity of pairs of first reflection grating sub-arrays is less than or equal to the first preset threshold; and
a quantity of pairs of second reflection grating sub-arrays is greater than the first preset threshold.

6. The structure according to claim 1, wherein for the at least one of the parallel resonators, the first reflection grating array comprises a first reflection grating sub-array;
the first reflection grating sub-array is disposed on an end portion of the first interdigital electrode array; and
a quantity of pairs of first reflection grating sub-arrays is less than or equal to the first preset threshold.

7. The structure according to claim 1, wherein for the at least one of the parallel resonators, the first reflection grating array comprises a first reflection grating sub-array;
the first reflection grating sub-array is disposed on an end portion of the first interdigital electrode array; and
a quantity of pairs of first reflection grating sub-arrays is greater than the first preset threshold.

8. The structure according to claim 1, wherein each of the parallel resonators further comprises a dielectric layer;
the dielectric layer is disposed on the first supporting substrate; and
a ratio of a thickness of the dielectric layer to a spacing between centers of first interdigital electrodes in the first interdigital electrode array is less than a fourth preset threshold, and the fourth preset threshold is less than a third preset threshold.

9. The structure according to claim 8, wherein the first supporting substrate is made of high-resistance silicon, quartz, sapphire, or silicon carbide.

10. The structure according to claim 1, wherein the first reflection grating array is arranged to form a slant angle with a normal direction of the first electrode array;
the first interdigital electrode array is arranged to form the slant angle with the normal direction of the first electrode array; and
the slant angle is set to within a range of [−10°, 10°].
